(19) United States
(12) Patent Application Publication
(10) Pub. No.: US 2006/0049492 A1
(43) Pub. Date: Mar. 9, 2006

(54) Reduced foot print lead-less package with tolerance for thermal and mechanical stresses and method thereof

(76) Inventors: Jeffrey Gail Holloway, Plano, TX (US); Sreenivasan K. Koduri, Allen, TX (US)

Correspondence Address: TEXAS INSTRUMENTS INCORPORATED, P O BOX 655474, M/S 3999, DALLAS, TX, 75265, US

(21) Appl. No.: 11/114,565

(22) Filed: Apr. 25, 2005

Related U.S. Application Data
(60) Provisional application No. 60/608,521, filed on Sep. 8, 2004.

(51) Int. Cl. H01L 23/495

(52) U.S. Cl. 257/666

(57) ABSTRACT

System and method for a reduced foot print package with tolerance for thermal and mechanical stresses for integrated circuits. A preferred embodiment comprises a package for an integrated circuit die comprising a plurality of input/output contacts and a die support to hold the integrated circuit die. The die support comprises a plurality of support arms, wherein each support arm is electrically disjoint and having an end with an exposed fuse lead that will be external of the packaged integrated circuit die. The exposed fuse leads can be used to fix the packaged integrated circuit die to a substrate and provide additional bonding strength to increase tolerance to thermal and mechanical stresses.

This application claims the benefit of U.S. Provisional Application No. 60/608,521, filed on Sep. 8, 2004, entitled “Enhanced Design and Process of a Lead-Less Plastic Package,” which application is hereby incorporated herein by reference.

### TECHNICAL FIELD

The present invention relates generally to a system and method for integrated circuits, and more particularly to a system and method for a reduced foot print package with tolerance for thermal and mechanical stresses for integrated circuits.

### BACKGROUND

Integrated circuit (IC) packages are subject to thermal and mechanical stresses after they have been solder mounted onto a printed circuit board or other types of substrates. Mechanical stresses can arise from physical sources, such as vibration, shock, flexing of the circuit board, and so on. Thermal stresses result from the different expansion and contraction rates of the various materials, such as the semiconductor substrate, the packaging material, the printed circuit board material, and so forth. Both the mechanical and thermal stresses can have negative effects upon the quality of the electrical contact of the solder mount. In severe cases, the stresses can result in the breakage of the electrical contact and render the IC inoperable.

One commonly used technique to help increase the package's tolerance to thermal and mechanical stresses involves the addition of a solder area located at the center of the bottom surface of the package. The additional area can permit an additional attachment point for the package to the printed circuit board. The attachment point is typically the size of the semiconductor die itself or larger and can also serve as a place holder for the die while the package is being formed. Therefore, the attachment area provided by the attachment point can be considerable. The use of the additional attachment point can increase the strength of the connection of the package to the printed circuit board.

Another technique that can be used to help increase the package's tolerance to thermal and mechanical stresses while not requiring the presence of the semiconductor die sized (or larger) attachment point in the middle of the package involves the use of a cross-brace type structure that can provide the addition of solder points, usually at the corners of the package where the soldered connections are most susceptible to damage due to the stress while elevating a center portion that can be used to hold the semiconductor die so that it does not protrude from the interior of the package. Since additional solder points are provided at the corners of the package, additional support is provided to help improve tolerance to thermal and mechanical stresses while signal routing is still permitted through the portion of the printed circuit board underneath the mounted package.

One disadvantage of the prior art is that the use of the additional attachment point in the center of the package can prevent the routing of electrical signals through the portion of the printed circuit board underneath the middle of the package. With a reduced routing area, the package may need to be enlarged to provide the needed signal routing. The use of a larger package can result in a larger overall printed circuit board and electronic device as well as lead to increased costs.

A second disadvantage of the prior art is that the use of the cross-brace structure adds additional solder points at the corners of the package, which can lead to an overcrowding of solder points at the corners. In order to have a good manufacturing yield, the solder points must be a certain distance apart (a value that can vary depending upon the particular manufacturing technique used) to ensure that electrical short circuits from misplaced solder does not occur. With the additional solder points, the spacing requirements may not be able to be maintained without changes in the design of the package. Furthermore, since the cross-brace structure is a monolithic entity, it is possible that short circuits occurring at the corners of the package result in the short circuit together of a large number of pins.

### SUMMARY OF THE INVENTION

These and other problems are generally solved or circumvented, and technical advantages are generally achieved, by preferred embodiments of the present invention, which provides a system and method for a reduced foot print integrated circuit package.

In accordance with a preferred embodiment of the present invention, a package for an integrated circuit die is provided. The package includes a plurality of input/output contacts and a die support to hold the integrated circuit die. The die support features a plurality of support arms with the support arms being electrically disjoint with respect to each other. Each support arm has an exposed fused lead end that lies on the outside of a completely packaged integrated circuit die that can be used to fix the completely packaged integrated circuit die to a substrate.

In accordance with another preferred embodiment of the present invention, a semiconductor product is provided. The semiconductor product includes an integrated circuit die and a plurality of input/output contacts that is electrically coupled to contacts on the integrated circuit die. The semiconductor product also includes a die support that is used to hold the integrated circuit die. The die support features a plurality of support arms with the support arms being electrically disjoint with respect to each other. Each support arm has an exposed fused lead end that lies on the outside of a completely packaged integrated circuit die and can be used to fix the completely packaged integrated circuit die to a substrate. Furthermore, the semiconductor product includes a body made from a mold compound. The integrated circuit die, the plurality of input/output contacts, and the die support are enclosed in the body with portions of each input/output contact and the exposed fused leads lying outside of the body.

In accordance with another preferred embodiment of the present invention, a method for manufacturing a packaged integrated circuit with increased tolerance to thermal and mechanical stresses is provided. The method includes mounting an integrated circuit die onto a die support with the die support having a plurality of support arms. Each support arm is electrically disjoint with respect to one another. Each support arm has an exposed fused lead that lies on the outside of the packaged integrated circuit and can be used to fix the packaged integrated circuit to a substrate. The method also includes electrically bonding contacts on the integrated circuit die to input/output contacts and placing a mold around the integrated circuit die and the input/output contacts. Finally, injecting a mold compound into the mold to form a package body.

An advantage of a preferred embodiment of the present invention is that tolerance to thermal and mechanical stresses are added to an integrated circuit package while preserving the ability to route signal wires underneath a portion of the printed circuit board where the package is mounted.

A further advantage of a preferred embodiment of the present invention is that the inclusion of a preferred embodiment of the present invention does not result in an overcrowding of solder points along the corners of the package. Therefore, the likelihood of an electrical short circuit is not increased. Furthermore, the design of a preferred embodiment of the present invention helps to stop an electrical short circuit from spreading, should one occur.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a through 1d are diagrams of different views of a lead-less package;

FIGS. 2a through 2d are diagrams of different views of a lead-less package with a prior art technique for providing an additional measure of tolerance to thermal and mechanical stresses, while permitting electrical routing on the printed circuit board under the package;

FIGS. 3a through 3d are diagrams of different views of a lead-less package with a technique for providing additional tolerance to thermal and mechanical stresses, according to a preferred embodiment of the present invention;

FIGS. 4a and 4b are diagrams of bottom views of lead frames, according to a preferred embodiment of the present invention;

FIGS. 5a and 5b are diagrams of different views of a lead-less package employing a technique for providing additional tolerance to thermal and mechanical stresses, according to a preferred embodiment of the present invention; and

FIG. 6 is a diagram of a sequence of events in the manufacture of a packaged integrated circuit in a lead-less package with increase tolerance to thermal and mechanical stresses, according to a preferred embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a lead-less package for an integrated circuit wherein increase tolerance to thermal and physical stresses are desired. The invention may also be applied, however, to other types of packages for integrated circuits, wherein there is a need for increased tolerance to thermal and physical stresses.

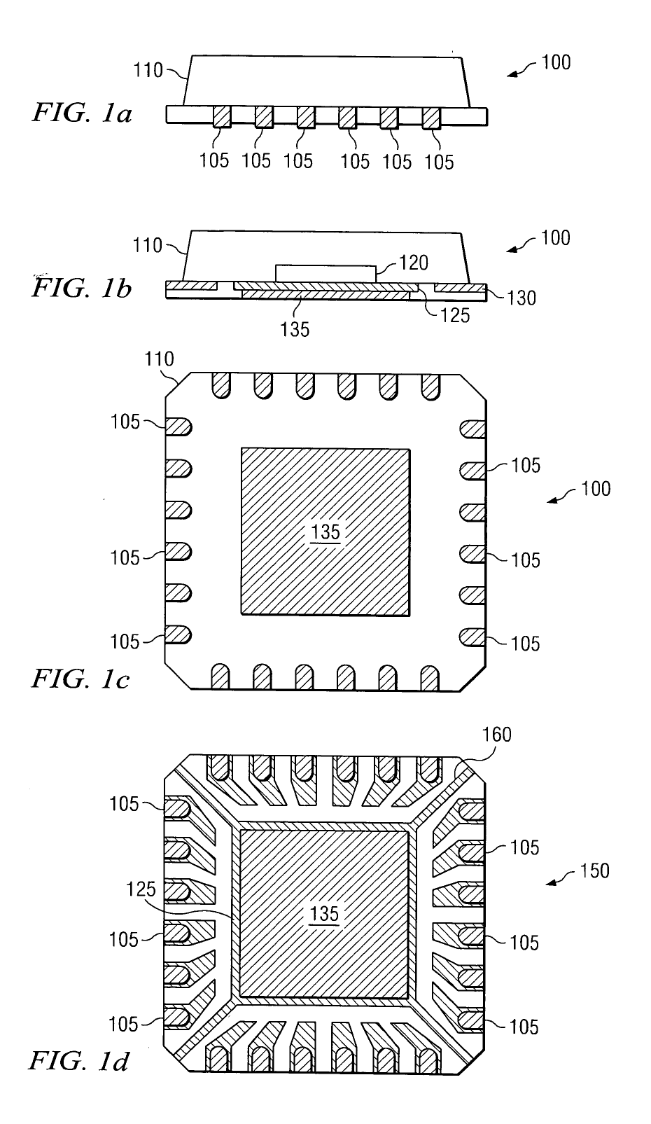

With reference now to FIGS. 1a through 1d, there are shown diagrams illustrating different views of a lead-less package 100 for an integrated circuit. The diagrams shown in FIGS. 1a, 1b, and 1c, illustrate side, side cross-sectional, and bottom views of the lead-less package 100, while FIG. 1d illustrates a bottom view of a lead-frame 150 present in the lead-less package 100. The diagrams shown illustrate an exemplary lead-less package 100 and lead-frame 150. Differences, such as number of pins, dimensions, and so forth, may exist in the wide variety of lead-less packages that are being used in electronic devices.

In this context, the term “pin” is used to describe an external contact point from the integrated circuit. While the external contact can physically be configured as a pin, it is understood that other types of contacts (e.g., solder balls in a ball grid array package, solder bumps, and so forth) also fall under the term “pin.”

The diagram shown in FIG. 1a illustrates a side view of the lead-less package 100. From the side, there can be seen a plurality of pins 105 and a main body 110 of the lead-less package 100. The main body 110 can be a solidified mold compound that can be poured or cast over the lead-frame 150 (not seen in FIG. 1a with exception of the pins 105). The main body 110 holds the integrated circuit and the lead-frame 150 in place and provides protection for the integrated circuit.

The diagram shown in FIG. 1b illustrates a side cross-sectional view of the lead-less package 100. As shown in FIG. 1b, the cross-sectional view of the lead-less package 100 is made from a cut made in the lead-less package 100 at approximately a midpoint of the lead-less package 100. In the cross-sectional view, an integrated circuit 120 can be seen, as well as a portion of a die attach paddle 125. The integrated circuit 120 may be bonded to the die attach paddle 125 by some bonding material, such as solder or glue, prior to the application of the mold compound. Once the mold compound solidifies, the integrated circuit 120 is sealed inside the hardened main body 110.

The cross-section of the die attach paddle displays an elevated portion 130, which can be used to hold the die attach paddle 125 in place during production and a thick base portion 135, which has at least a surface that extends below the solidified mold compound 110 and is not covered by the main body 110. The surface that is external to the main body 110 can allow the attachment of the lead-less package 100 to a printed circuit board. The attachment can be made using solder or glue.

The diagram shown in FIG. 1c illustrates a bottom view of the lead-less package 100. From the bottom side, there can be seen the thick base region 135 of the die attach paddle 125 and the pins 105 of the lead-less package 100. As discussed previously, the thick base region 135 can be a part of the die attach paddle 125 that extends to the exterior of the lead-less package 100 after the application of the mold compound and can permit the attachment of the lead-less package 100 to a printed circuit board (or some other substrate).

The diagram shown in FIG. 1d illustrates a bottom view of the lead-frame 150. Note that for discussion purposes, portions of the lead-frame 150 that will be internal to the lead-less package 100 after formation are shown cross-hatched with a negative 45-degree pattern while the portions that will be external to the lead-less package 100 are shown cross-hatched with a positive 45-degree pattern. This cross-hatching pattern is consistent for other figures in this discussion. The lead-frame 150 may provide electrical connectivity from the integrated circuit 120 to external signal lines as well as a way to hold the integrated circuit 120 in place while the lead-less package 100 is being formed by applying liquefied mold compound over the lead-frame 150 and molding the lead-less package 100 into a desired shape. The lead-frame 150 includes pins 105 that can be used to conduct electrical signals to and from the integrated circuit 120 as well as the die attach paddle 125 that can be used to hold the integrated circuit 120 during the formation of the lead-less package 100.

The die attach paddle 125 can be held in position by a plurality of tie bars 160. The tie bars 160 can extend from the corners of the lead-frame 150 and provide a measure of rigidity during the formation of the lead-less package 100, before the solidification of the mold compound.

A disadvantage of the thick base region 135 that permits the attachment of the lead-less package 100 to the printed circuit board is that its presence can prevent the routing of signal lines through that area of the printed circuit board. The signal lines must be routed using other portions of the printed circuited board that are outside the package outline and thereby potentially increasing the overall size of the printed circuit board.

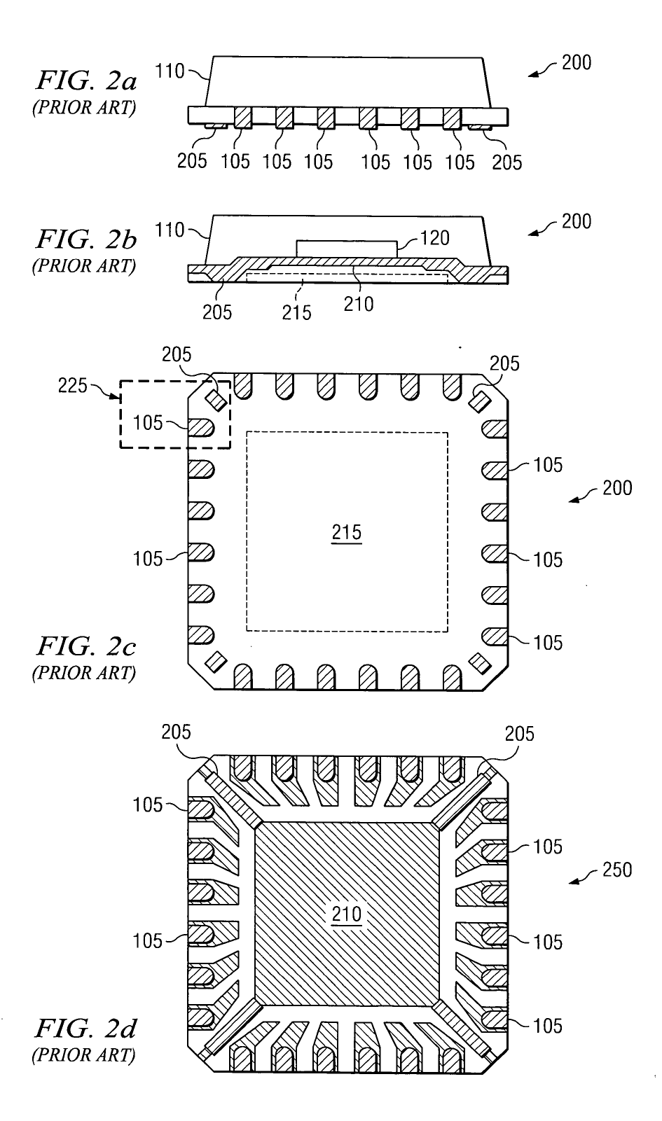

With reference now to FIGS. 2a through 2d, there are shown diagrams illustrating different views of a lead-less package 200 for an integrated circuit, wherein the lead-less package 200 makes use of a prior art technique for providing an additional measure of tolerance to thermal and mechanical stresses. The diagrams shown in FIGS. 2a, 2b, and 2c, illustrate side, side cross-sectional, and bottom views of the lead-less package 200 with additional tolerance to thermal and mechanical stresses, while FIG. 2d illustrates a bottom view of a lead-frame 250 present in the lead-less package 200. The diagrams shown illustrate an exemplary lead-less package 200 and lead-frame 250. Differences, such as number of pins, dimensions, and so forth, may exist in the wide variety of lead-less packages that are being used in electronic devices.

The diagram shown in FIG. 2a illustrates a side-view of the lead-less package 200. The side view of the lead-less package 200 is substantially similar to the side-view of the lead-less package 100 (FIG. 1a), wherein a plurality of pins 105 and a main body 110 (made from a mold material) of the lead-less package 200 can be seen. Also seen in the side-view of the lead-less package 200 are exposed tie-bars 205. The exposed tie-bars 205 can be used as additional attachment points for the lead-less package 200 to the printed circuit board (or substrate). In most packaging applications the exposed tie-bars 205 are located at the corners of the lead-less package 200, where the majority of the stress occurs.

The diagram shown in FIG. 2b illustrates a side cross-sectional view of the lead-less package 200. In the cross-sectional view, the integrated circuit 120 can be seen as well as an internal structure of the exposed tie-bars 205. As shown, the exposed tie-bars 205 are a portion of a die attach paddle 210 that can be used to hold the integrated circuit 120 in position while bond wire is used to attach the pins 105 to various input/output pads on the integrated circuit and when the mold compound is first injected and then hardens. Note that having the exposed tie-bars 205 be a part of the same entity as the die attach paddle 210 can simplify manufacture of the lead-less package 200, especially when compared to a situation wherein the two are separate entities.

The die attach paddle 210 has an elevated portion through a central region 215 of the lead-less package 200 so that once the mold compound is injected and hardens, the central region 215 of the lead-less package 200 is clear of conductive materials. This can therefore permit the routing of signal wires through a portion of the printed circuit board that is immediately below the central region 215 of the lead-less package 200.

The diagram shown in FIG. 2c illustrates a bottom view of the lead-less package 200. From the bottom side, the central region 215 of the lead-less package 200 is clear of attachment points that can prohibit the routing of signal wires in the printed circuit board. Visible in the bottom view of the lead-less package 200 are the pins 105 and the exposed tie-bars 205. The position of the tie-bars 205 at the corners of the lead-less package 200 can significantly improve the tolerance to thermal and mechanical stresses since the majority of the stress occurs at the corners of the lead-less package 200. Furthermore, the size of the exposed tie-bars 205 can be increased or decreased to meet desired stress tolerance levels. Note that if the size of the exposed tie-bars 205 were to be increased, a corresponding increase in the size of the lead-less package 200 may be necessary.

The presence of the exposed tie-bars 205 in the lead-less package 200 may present some difficulties in the manufacture of circuits using the lead-less package 200. Depending upon the manufacturing process used, a certain amount of spacing must be maintained between pins 105 to ensure that when the lead-less package 200 is soldered to the printed circuit board electrical short circuits due primarily to displaced solder are prevented. The exposed tie-bars 205 may be too close to the pin 105 and the required spacing may be violated. If this spacing is violated, the probability of a short circuit occurring between a pin 105 and an exposed tie-bar 205, for example, in location highlighted as 225, may be increased. Furthermore, since all of the exposed tie-bars 205 are formed from the die-attach paddle 210, all of the exposed tie-bars 205 are at a single electrical potential. Therefore, if more than one short circuit occurs between the exposed tie-bars 205 and the pins 105, then all of the pins 105 so short circuited will be held at a single electrical potential. This will most likely lead to an improperly operating circuit.

The diagram shown in FIG. 2d illustrates a bottom view of the lead-frame 250. Note that for discussion purposes, portions of the lead-frame 250 that will be internal to the lead-less package 200 after formation are shown cross-hatched with a negative 45-degree pattern while the portions that will be external to the lead-less package 200 are shown cross-hatched with a positive 45-degree pattern. The bottom view of the lead-frame 250 clearly illustrates the die-attach paddle 210 along with its four exposed tie-bars 205 that permit attachment of the corners of the lead-less package 200 to the printed circuit board.

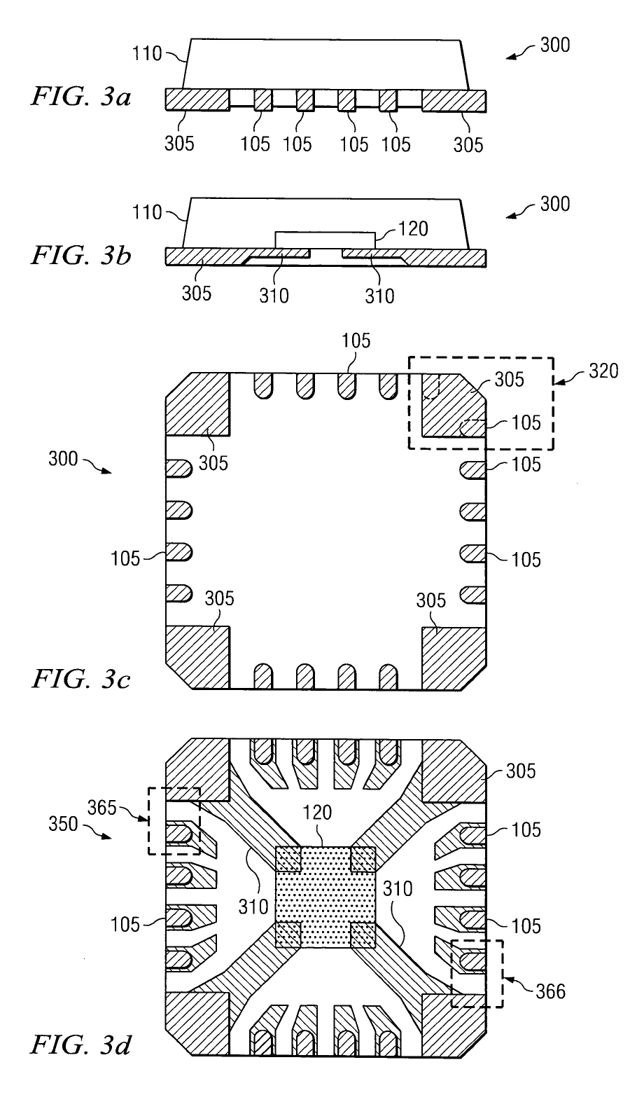

With reference now to FIGS. 3a through 3d, there are shown diagrams illustrating different views of a lead-less package 300 for an integrated circuit, wherein the lead-less package 300 makes use of a technique for providing an additional measure of tolerance to thermal and mechanical stresses, according to a preferred embodiment of the present invention. The diagrams shown in FIGS. 3a, 3b, and 3c, illustrate side, side internal, and bottom views of the lead-less package 300, while FIG. 3d illustrates a bottom view of a lead-frame 350 present in the lead-less package 300. The diagrams shown illustrate an exemplary lead-less package 300 and lead-frame 350. Differences, such as number of pins, dimensions, and so forth, may exist in the wide variety of lead-less packages that are being used in electronic devices.

The diagram shown in FIG. 3a illustrates a side view of the lead-less package 300. The side view of the lead-less package 300 features a plurality of pins 105 and a main body 110 made from a mold material. As viewed from the side, the lead-less package 300 also features exposed fused leads 305. According to a preferred embodiment of the present invention, the exposed fused leads 305 can be located at the corners of the lead-less package 300 and can be used to provide additional tolerance to thermal and mechanical stresses when they are used to attach the lead-less package 300 to the printed circuit board. Comparing the exposed fused leads 305 to the exposed tie-bars 205 (FIG. 2a), the exposed fused leads 305 can have a larger surface area than the exposed tie-bars 205. The increased surface area can yield a stronger bond between the lead-less package 300 and the printed circuit board, leading to a greater degree of tolerance to the thermal and mechanical stresses.

The diagram shown in FIG. 3b illustrates a side internal view of the lead-less package 300. In the internal view, the integrated circuit 120 can be seen resting upon die supports 310. The external fused leads 305 are a part of the die supports 310. Note that the die supports 310 are not as thick as the external fused leads 305, therefore, when the mold compound is injected and hardens, the portion of the die supports 310 that do not make up the external fused leads 310 is internal to the lead-less package 300. Since the die supports 310 are internal to the lead-less package 300, it can be possible to route signal lines on the printed circuit board underneath the lead-less package 300.

The diagram shown in FIG. 3c illustrates a bottom view of the lead-less package 300. From the bottom view, the pins 105 and the exposed fused leads 305 can be clearly seen. The relatively large surface area of the exposed fused leads 305 can afford a greater bond between the lead-less package 300 and the printed circuit board, thereby increasing the lead-less package's ability to tolerate thermal and mechanical stresses. Since the exposed fused leads 305 are designed to be located at the corner of the lead-less package 300 and not to be fitted in between two existing pins, it can be easier to maintain manufacturing spacing requirements to reduce the chance of short circuits due to displaced solder. According to a preferred embodiment of the present invention, the exposed fused leads 305 can occupy a surface area normally reserved for one or more pins 105 located at the corners of the lead-less package 300. For example, the exposed fused leads 305, as shown in FIG. 3c, occupy an area delineated by a pin closest to each corner where the exposed fused leads are located. Refer to expanded highlight 320 for a detailed view of an exemplary exposed fused lead that occupies an area normally used by one pin.

The diagram shown in FIG. 3d illustrates a bottom view of the lead-frame 350. According to a preferred embodiment of the present invention, the die supports 310 are designed so that they are disjoint (at least, electrically disjoint). By being electrically disjoint, the die supports 310 may not be at a common electrical potential, unless by design by electrically connecting the exposed fused leads 305. Since the die supports 310 are electrically disjoint, should a short circuit occur between an exposed fused lead 305 and an adjacent pin (such as at highlight 365), an undesired situation wherein another short circuit between another exposed fused lead and a pin that is adjacent to it (such as at highlight 366) will not lead to placing both pins at the same electrical potential.

While the die supports 310 are disjoint, they should be designed with sufficient length to hold the integrated circuit 120 with adequate stability to perform bonding with the pins 105 as well as the injection of the mold compound to form the lead-less package 300.

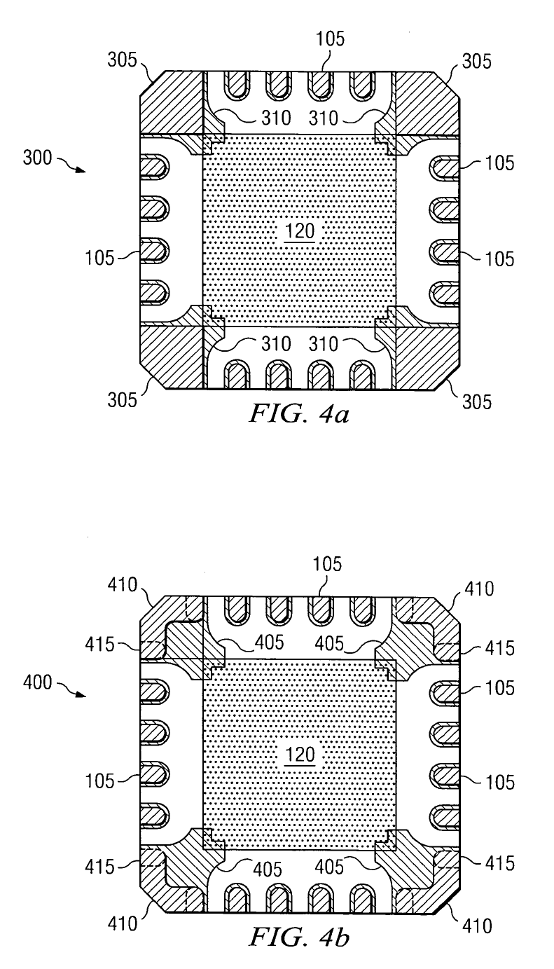

With reference now to FIGS. 4a and 4b, there are shown diagrams illustrating bottom views of lead-frames, according to a preferred embodiment of the present invention. As shown in FIG. 4a, the integrated circuit 120 in the lead-frame 350 is larger than in that shown in previous figures. However, the corners of the integrated circuit 120 can overlay the exposed fused leads 305 of the die supports 310 without ill effect. The diagram shown in FIG. 4b illustrates lead-frame 400 that features a modification to the lead-frame 350 to enable a greater amount of the circuit board under the package for electrical routing.

The lead-frame 400 includes die supports 405 featuring an exposed fused area 410 that has been relieved to create a larger area wherein additional circuitry can be placed on the circuit board. According to a preferred embodiment of the present invention, the exposed fused area 410 can be relieved to a point wherein the exposed fused area 410 maintains coverage of corner pins 415 (if the exposed fused area 410 were not present). By sizing the exposed fused area 410 so that it encompasses an area at least as large as one that would contain the corner pins 415, a sufficiently large surface area is provided to provide good tolerance to thermal and mechanical stresses. Furthermore, by occupying the positions that would normally be allocated to pins at the corners of the lead-frame 400, the probability of a short circuit occurring between the exposed fused lead 410 and pins 105 adjacent to it are substantially equal to the probability of a short circuit occurring between adjacent pins. Additionally, a test socket already designed to fit a similar lead-frame with separate pins at the corners can be used with little or no change for the lead-frame 400 with the fused pins.

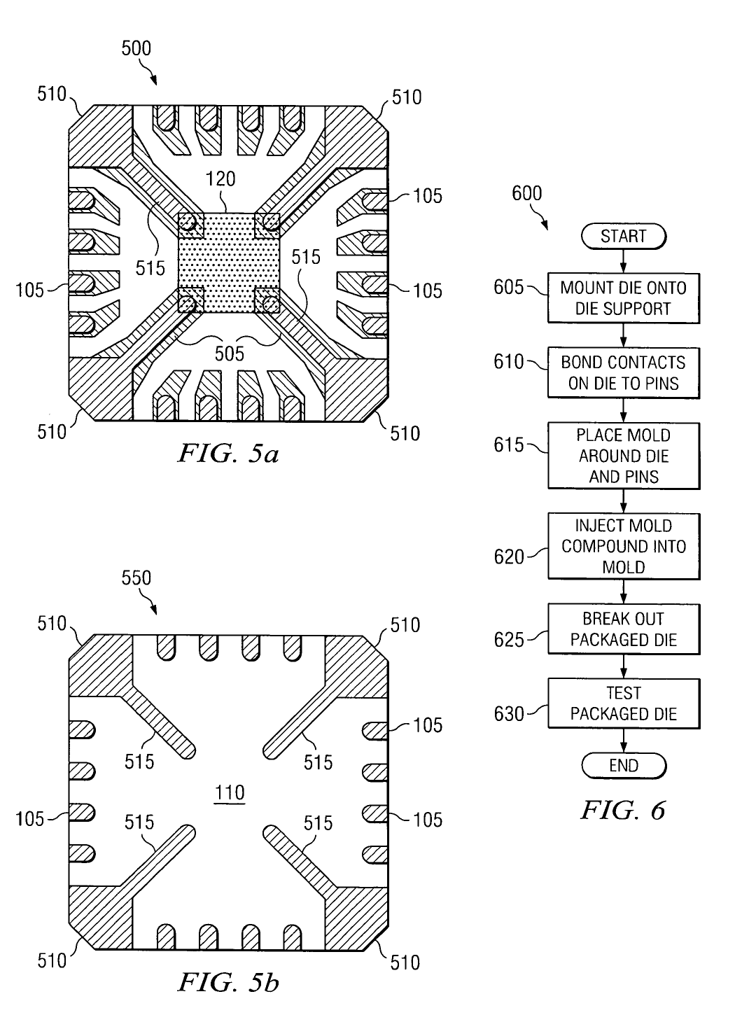

With reference now to FIGS. 5a and 5b, there are shown diagrams illustrating different views of a lead-frame 500 and a lead-less package 550 employing a technique for providing additional tolerance to thermal and mechanical stresses, according to a preferred embodiment of the present invention. The diagram shown in FIG. 5a illustrates a bottom view of the lead-frame 500. As displayed in FIG. 5a, there is shown the lead-frame 500 with die supports 505 that can be used to hold the integrated circuit 120 in position while the lead-less package 550 is being formed. The die supports 505 are designed so that they are electrically disjoint and feature exposed fused leads 510. In addition to the exposed fused leads 510, the die supports 505 also have an enhanced region, referred to as an external support 515, running a significant portion of the length of the die support 505. The external support 515 can be used to prevent flexing that may occur when the integrated circuit 120 is placed onto the die supports 505 and during wire bonding of contacts on the integrated circuit and pins of the lead-less package 550. The external support 515 can reduce or eliminate the flexing. According to a preferred embodiment of the present invention, the resistance to flexing of the external support 515 can be achieved by making the external support 515 thicker than the thickness of the die support 505, with a maximum thickness being substantially equal to the thickness of the exposed fused leads 510. In situations where it is difficult or impossible to employ the external support 515, full thickness pins may be extended toward the center of a lead-frame during package assembly.

The diagram shown in FIG. 5b illustrates a bottom view of the lead-less package 550. The bottom view clearly shows the external support 515 being exterior to the main body 110. Since the external support 515 is external to the main body 110, they can be used to further strengthen the bond between the lead-less package 550 and the circuit board. Note however, that since the external supports 515 do not touch, electrical routing on the printed circuit board underneath the lead-less package 550 can still occur.

With reference now to FIG. 6, there is shown a diagram illustrating a sequence of events 600 involved in the manufacture of a packaged integrated circuit in a lead-less package with increased tolerance to thermal and mechanical stresses, according to a preferred embodiment of the present invention. The manufacture of the packaged integrated circuit can begin with the mounting of an integrated circuit die onto die supports, such as die supports 310 (FIG. 3d) and 405 (FIG. 4b) of a lead-frame (block 605).

According to a preferred embodiment of the present invention, the die supports onto which the die is mounted are electrically disjoint and each features an exposed fused lead, such as exposed fused leads 305 (FIG. 3d) and 410 (FIG. 4b). After the die has been mounted onto the die supports, electrical connections on the die can be connected to corresponding pins in the lead-frame (block 610). The bonding can be accomplished via the use of electrical wires, such as bond wire. The pins in the lead-frame can be used to provide electrical power as well as signal input and output to the die.

After the electrical connections have been made, a mold can be placed around the lead-frame (block 615) and mold compound can be injected into the mold (block 620). Once the mold compound solidifies, the mold can be removed and the packaged die can be broken out (block 625). According to a preferred embodiment of the present invention, the lead-frame can be arranged in an array of lead-frames to facilitate rapid production, and after the mold compound solidifies, the individual packaged dies can be separated from one another. The packaged die is now complete and can undergo testing to verify proper function (block 630).

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A package for an integrated circuit die, the package comprising:
a plurality of input/output contacts; and
a die support to hold the integrated circuit die, the die support comprising a plurality of support arms, wherein each support arm is electrically disjoint, each support arm having an end with an exposed fused lead that will lay external to a completely packaged integrated circuit die and is used to fix the completely packaged integrated circuit die to a substrate.

2. The package of claim 1, wherein the package has a rectangular shape, wherein the input/output contacts are arranged around a perimeter of the package, and wherein the exposed fused leads are located at corners of the package.

3. The package of claim 2, wherein the die support has four support arms, and wherein the exposed fused leads of the four support arms are each located at a corner of the package.

4. The package of claim 2, wherein the exposed fused lead of a support arm occupies an area originally intended for a pair of input/output contacts, each input/output contact of the pair being a closest contact along a side of a corner where the exposed fused lead is located.

5. The package of claim 4, wherein the exposed fused lead is relieved to maximize an area of the printed circuit board that can be used for electrical routing.

6. The package of claim 1, wherein a minimum separation between an exposed fused lead and a closest input/output contact is at least equal to a minimum separation between adjacent input/output contacts.

7. The package of claim 1, wherein the package is part of a linear array of packages, coupled together prior to manufacture.

8. The package of claim 1, wherein portions of each input/output contact lies external to the completely packaged integrated circuit die.

9. The package of claim 1, wherein each support arm of the die support has an external support to reduce flexing of the support arm during assembly.

10. The package of claim 1, wherein the input/output contact is a pin, solder bump, or solder ball.

11. A semiconductor product comprising:
an integrated circuit die;
a plurality of input/output contacts electrically coupled to contacts on the integrated circuit die;
a die support to hold the integrated circuit die, the die support comprising a plurality of support arms, wherein each support arm is electrically disjoint, each support arm having an end with an exposed fused lead that will lay external to a completely packaged integrated circuit die and is used to fix the completely packaged integrated circuit die to a substrate; and
a body made from a mold compound, wherein the integrated circuit die, the plurality of input/output contacts, and the die support are enclosed in the body with portions of each input/output contact and the exposed fused lead of each support arm laying external to the body.

12. The semiconductor product of claim 11, wherein the integrated circuit die is bonded to the die support, and wherein contacts on the integrated circuit die are coupled to the plurality of input/output contacts to provide electrical and signal connectivity.

13. The semiconductor product of claim 12, wherein the integrated circuit die, the plurality of input/output contacts, and the die support are embedded in the body after the integrated circuit die is bonded to the die support and the contacts on the integrated circuit die are coupled to the plurality of input/output contacts.

14. The semiconductor product of claim 11, wherein the body is formed by placing the integrated circuit die, the plurality of input/output contacts, and the die support into a mold and injected the mold compound into the mold.

15. The semiconductor product of claim 11, wherein the semiconductor product is attached to a substrate by a soldering technique, and wherein there is no conductive surface on a bottom surface of the semiconductor product so that signal lines can be routed on the substrate immediately underneath the semiconductor product.

16. The semiconductor product of claim 11, wherein the exposed fused leads are attached to a substrate to help strengthen a bond between the semiconductor device and the substrate.

17. A method for manufacturing a packaged integrated circuit with increased tolerance to thermal and mechanical stresses, the method comprising:
mounting an integrated circuit die onto a die support, wherein the die support comprises a plurality of support arms, wherein each support arm is electrically disjoint, each support arm having an end with an exposed fused lead that will lay external to the packaged integrated circuit and can be used to fix the packaged integrated circuit to a substrate;
electrically bonding contacts on the integrated circuit die to input/output contacts;
placing a mold around the integrated circuit die and the input/output contacts; and
injecting a mold compound into the mold to form a package body.

18. The method of claim 17 further comprising after the injecting, testing the packaged body.

19. The method of claim 17, wherein the die support and input/output contacts are arranged as a single unit, wherein the single unit is replicated and arranged in an array fashion to facilitate the simultaneous manufacture of multiple packaged integrated circuits, and the method further comprising after the injecting, separating the packaged bodies.

20. The method of claim 17, wherein the packaged integrated circuit has a side that is facing the substrate, and wherein the side has a central region that is free of conductive material so that signal lines can be routed in a portion of the substrate that lies beneath the central region.
